(19) United States
(12) Patent Application Publication
(10) Pub. No.: US 2024/0161820 A1
(43) Pub. Date: May 16, 2024

(54) METHOD AND DEVICE FOR OPERATING A MEMORY DEVICE

(71) Applicant: Robert Bosch GmbH, Stuttgart (DE)

(72) Inventors: Taha Soliman, Renningen (DE); Tobias Kirchner, Ludwigsburg (DE)

(21) Appl. No.: 18/503,479

(22) Filed: Nov. 7, 2023

(30) Foreign Application Priority Data
Nov. 11, 2022 (DE) 10 2022 211 998.3

(51) Int. Cl. G11C 11/412; G11C 5/06; G11C 11/418

(52) U.S. Cl. CPC G11C 11/412; G11C 5/063; G11C 11/418

(57) ABSTRACT

A method for operating a memory device comprising at least one memory unit. The at least one memory unit includes a bistable multivibrator and two access transistors for the controllable connection of the bistable multivibrator to two secondary control lines associated with the at least one memory unit. The connection of the bistable multivibrator to the two secondary control lines can be controlled using a first primary control line. The method includes: applying a control signal to a control terminal of at least one of the two access transistors in such a way that a load path of the at least one access transistor is at least partially electrically conductive, with respect to a high-resistance state of the load path of the at least one access transistor; determining a first variable which characterizes at least one current flowing through the load path of the at least one access transistor.

### CROSS REFERENCE

The present application claims the benefit under 35 U.S.C. § 119 of German Patent Application No. DE 10 2022 211 998.3 filed on Nov. 11, 2022, which is expressly incorporated herein by reference in its entirety.

### FIELD

The present invention relates to a method for operating a memory device.

The present invention further relates to a device for operating a memory device.

### SUMMARY

Exemplary embodiments of the present invention relate to a method for operating a memory device which comprises at least one memory unit, for example memory cell, wherein the at least one memory unit comprises a bistable multivibrator and two access transistors for the controllable connection of the bistable multivibrator to two secondary control lines, for example bit lines, associated with the at least one memory unit, wherein, for example, the connection of the bistable multivibrator to the two secondary control lines can be controlled by means of a first primary control line, for example word line, wherein the method comprises: application of a control signal, for example a control voltage, to a control terminal of at least one of the two access transistors in such a way that a load path of the at least one access transistor is at least partially electrically conductive, for example with respect to a high-resistance state of the load path of the at least one access transistor, for example less electrically conductive with respect to a low-resistance state of the load path of the at least one access transistor; determination of a first variable which characterizes at least one current flowing through the load path of the at least one access transistor.

In further exemplary embodiments of the present invention, information about a memory content of the at least one memory unit can, for example, be obtained thereby. In further exemplary embodiments, the principle according to the embodiments can be applied, for example, to a possible plurality of memory units of the memory device, whereby, for example, information about a memory content of the plurality of memory units of the memory device is obtained, for example simultaneously, which can be used in further exemplary embodiments, for example, for performing computing operations on the basis of the information obtained.

In further exemplary embodiments of the present invention, it is provided that the control signal is applied to the control terminal of the at least one of the two access transistors via the primary control line, for example word line.

In further exemplary embodiments of the present invention, the at least one memory unit is designed as a static RAM (random access memory) memory cell or forms a static RAM memory cell.

In further exemplary embodiments of the present invention, the bistable multivibrator has a plurality of field-effect transistors, for example of the MOSFET type.

In further exemplary embodiments of the present invention, the two access transistors are designed as field-effect transistors, for example of the MOSFET type.

In further exemplary embodiments of the present invention, it is provided that the method comprises: application of the control signal to both access transistors, for example via the primary control line, for example word line. In further exemplary embodiments, for example, the determination of the first variable can thus, for example, be performed on the basis of two currents, of which a first current is a current flowing through the load path (e.g., drain-source path) of the first access transistor, and of which a second current is a current flowing through the load path of the second access transistor. In further exemplary embodiments, the first variable can be determined on the basis of the first current and of the second current, for example using a differential measuring principle.

In further exemplary embodiments of the present invention, it is provided that the application of the control signal to the control terminal of the at least one of the two access transistors in such a way that the load path of the at least one access transistor is at least partially electrically conductive, for example with respect to the high-resistance state of the load path of the at least one access transistor (but, for example, is less electrically conductive than in a low-resistance state, for example in the case of a field-effect transistor characterizable by a resistance R_{DS,on}), comprises: application of a control voltage to the control terminal of the at least one of the two access transistors, which control voltage is less than or equal to a threshold voltage of the at least one access transistor.

In further exemplary embodiments of the present invention, the setting of the control voltage to less than or equal to the threshold voltage of the at least one access transistor enables a, for example purposeful, “removal” of electrical charge from the bistable multivibrator, i.e., for example, a purposeful discharge of an electrical current from the bistable multivibrator through the at least one access transistor, wherein a value of the current depends, for example, on the state of the bistable multivibrator.

In further exemplary embodiments of the present invention, it is provided that the memory device has a plurality of memory units, for example memory cells, wherein the method comprises: application of the control signal, for example the control voltage, to a relevant control terminal of at least one of the two access transistors of the plurality of memory units in such a way that a load path of the relevant at least one access transistor of the plurality of memory units is at least partially electrically conductive, for example with respect to a high-resistance state of the load path of the at least one access transistor (e.g., by selecting the control voltage to be less than or equal to the threshold voltage of the at least one access transistor); determination of the first variable which characterizes a sum of currents flowing through the respective load paths of the at least one access transistor of the plurality of memory units, wherein this sum can, for example, be a summation current from the individual access transistors, such as can be conducted, for example, via at least one of the secondary control lines, for example bit lines, for example to a device for determining the first variable or the summation current, for example comprising at least one measuring device.

In further exemplary embodiments of the present invention, it is provided that the application is performed using at least the first primary control line.

In other words, in further exemplary embodiments of the present invention, it is provided that a plurality of memory units, for example memory cells, of the memory device are activated, for example simultaneously, for example by the application of the control signal, for example the control voltage, to a relevant control terminal of at least one of the two access transistors of the plurality of memory units in such a way that a load path of the relevant at least one access transistor of the plurality of memory units is at least partially electrically conductive, for example with respect to a high-resistance state of the load path of the at least one access transistor (e.g., by selecting the control voltage to be less than or equal to the threshold voltage of the at least one access transistor).

In further exemplary embodiments of the present invention, activation can be effected, for example, by applying the relevant control voltage, for example less than or equal to the threshold voltage, via at least the first primary control line, for example a word line, possibly also via a plurality (e.g., if present) of primary control lines, for example word lines. In further exemplary embodiments, a current that can be discharged from the relevant plurality of memory units can be discharged, for example, via at least one bit line associated with the relevant memory unit, and optionally, for example, measured.

In further exemplary embodiments of the present invention, it is provided that the method comprises: determination of the first variable with a, for example, current-based, analog/digital converter device, for example a differential analog/digital converter device, and/or with another determination device, for example measuring device, suitable for this purpose.

In further exemplary embodiments of the present invention, it is provided that the determination device, for example measuring device, is connected and/or connectable to at least one of the bus lines. In further exemplary embodiments, it is provided that the determination device, for example measuring device, can, for example, be combined with, for example integrated in, an existing, for example conventional, measuring device, which is designed, for example, in the case of a complete activation of the access transistors, for reading a content of the memory unit(s), which can be performed, for example, by means of a voltage measurement.

In further exemplary embodiments of the present invention, it is provided that the method comprises at least one of the following elements: a) at least a temporary operation of the memory device in a first, for example digital, operating mode in which, for the application to the control terminal of the at least one of the two access transistors, a control voltage is used that is greater than the threshold voltage of the at least one of the two access transistors (e.g., for conventional reading of the memory content); b) at least a temporary operation of the memory device in a second, for example analog, operating mode, in which, for the application to the control terminal of the at least one of the two access transistors, a control voltage is used that is less than or equal to the threshold voltage of the at least one of the two access transistors (e.g., for determining at least one current, for example according to exemplary embodiments).

Further exemplary embodiments of the present invention relate to a device for performing the method according to the embodiments of the present invention.

In further exemplary embodiments of the present invention, it is provided that the device comprises at least one of the following elements: a) device for the application of the control signal to the control terminal of at least one of the two access transistors, for example via the first primary control line; b) analog/digital converter device, for example current-based analog/digital converter device, for example differential analog/digital converter device; c) measuring device, for example measuring amplifier, for determining at least one electrical potential or one potential difference, which is or are associated with at least one of the secondary control lines, for example bit lines.

In further exemplary embodiments of the present invention, it is provided that the device comprises at least one memory device which comprises at least one memory unit, for example memory cell, wherein the at least one memory unit comprises a bistable multivibrator and two access transistors for the controllable connection of the bistable multivibrator to two secondary control lines, for example bit lines, associated with the at least one memory unit, wherein, for example, the connection of the bistable multivibrator to the two secondary control lines can be controlled by means of a first primary control line, for example word line.

In further exemplary embodiments of the present invention, it is provided that a conventional memory unit or memory device can be expanded by at least one aspect of the principle according to the embodiments, for example by the assignment, for example provision, of at least one of the following elements: a) device for the application of the control signal to the control terminal of at least one of the two access transistors, for example via the first primary control line; b) analog/digital converter device, for example current-based analog/digital converter device, for example differential analog/digital converter device; c) measuring device, for example measuring amplifier, for the determination of at least one electrical potential or one potential difference, which is or are associated with at least one of the secondary control lines, for example bit lines. In further exemplary embodiments, it is provided that at least one of the aforementioned aspects a), b), c) can be assigned into the conventional memory unit or memory device or to the conventional memory unit or memory device.

Further exemplary embodiments of the present invention relate to a computing device, for example a vector matrix multiplication device, VMM, comprising at least one device according to the embodiments.

Further exemplary embodiments of the present invention relate to a use of the method according to the embodiments and/or of the device according to the embodiments and/or of the computing device according to the embodiments for at least one of the following aspects: a) the processing of a current associated with the bistable multivibrator; b) the evaluation an output current of the bistable multivibrator; c) the determination of a sum of output currents of bistable multivibrators of a plurality of memory units, for example memory cells, of the device; d) the provision of a computing device, for example, for algorithms of artificial intelligence, for example for executing an inference of an artificial neural network; e) the expansion of a, for example conventional, memory cell, for example for reading or determining an output current of the bistable multivibrator.

Further features, possible applications, and advantages of the present invention emerge from the following description of exemplary embodiments of the present invention, which are shown in the figures. In this case, all of the features described or shown form the subject-matter of the present invention individually or in any combination, irrespective of their wording or representation in the description herein or in the figures.

### BRIEF DESCRIPTION OF THE DRAWINGS

FIG. 1 schematically shows a simplified circuit diagram according to exemplary embodiments of the present invention.

FIG. 2 schematically shows a simplified block diagram according to exemplary embodiments of the present invention.

FIG. 3 schematically shows a simplified flowchart according to further exemplary embodiments of the present invention.

FIG. 4 schematically shows a simplified flowchart according to further exemplary embodiments of the present invention.

FIG. 5 schematically shows a simplified circuit diagram according to further exemplary embodiments of the present invention.

FIG. 6 schematically shows a simplified flowchart according to further exemplary embodiments of the present invention.

FIG. 7 schematically shows aspects of uses according to further exemplary embodiments of the present invention.

### DETAILED DESCRIPTION OF EXAMPLE EMBODIMENTS

Exemplary embodiments of the present invention, see, for example, FIGS. 1, 2 and 3, relate to a method for operating a memory device 100 (FIG. 1) which comprises at least one memory unit, for example memory cell, 110, wherein the at least one memory unit 110 comprises a bistable multivibrator KS and two access transistors T5, T6 for the controllable connection of the bistable multivibrator KS to two secondary control lines, for example bit lines, SL2a, SL2b, associated with the at least one memory unit 110, wherein, for example, the connection of the bistable multivibrator KS to the two secondary control lines SL2a, SL2b can be controlled by means of a first primary control line, for example word line, SL1-1, wherein the method comprises: the application 200 of a control signal, for example a control voltage, V-CTRL, to a control terminal T5-G (FIG. 1) (e.g., gate electrode, in the case of a design of the transistor T5 as a MOSFET) of at least one of the two access transistors T5, T6, in such a way that a load path T5-LS of the at least one access transistor T5 is at least partially electrically conductive, for example with respect to a high-resistance state of the load path T5-LS of the at least one access transistor T5, for example less electrically conductive with respect to a low-resistance state of the load path T5-LS of the at least one access transistor T5; the determination 202 of a first variable G1 which characterizes at least one current I1a flowing through the load path T5-LS of the at least one access transistor T5.

In further exemplary embodiments, information about a memory content of the at least one memory unit 110 can, for example, be obtained thereby.

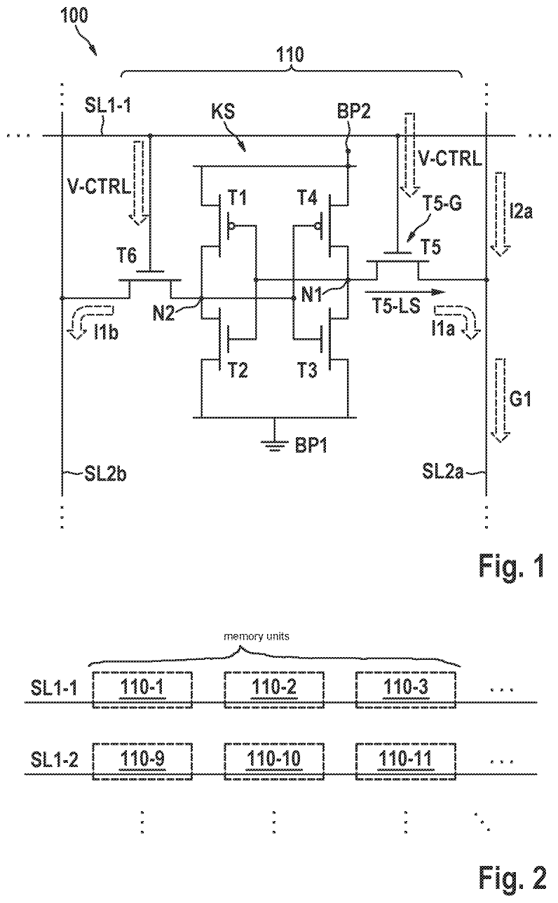

In further exemplary embodiments, FIG. 2, the principle according to the embodiments can be applied, for example, to a possible plurality of memory units 110-1, 110-2, . . . , 110-11, . . . of the memory device 100, whereby, for example, information about a memory content of the plurality of memory units 110-1, 110-2, . . . , 110-11, . . . of the memory device is obtained, for example simultaneously, which can be used, for example, in further exemplary embodiments for performing computing operations on the basis of the information obtained.

In further exemplary embodiments, FIG. 1, it is provided that the application 200 of the control signal V-CTRL to the control terminal T5-G of the at least one of the two access transistors T5, T6 is performed via the primary control line, for example word line, SL1-1.

In further exemplary embodiments, FIG. 1, the at least one memory unit 110 is designed as a static RAM (random access memory) memory cell or forms a static RAM memory cell.

In further exemplary embodiments, FIG. 1, the bistable multivibrator KS has a plurality of field-effect transistors T1, T2, T3, T4, for example of the MOSFET type, which are, for example, connected in the manner shown in FIG. 1. The reference sign BP1 symbolizes, by way of example, a first electrical reference potential, for example ground potential. The reference sign BP2 symbolizes, by way of example, a second electrical reference potential, for example operating voltage potential, which is different from the ground potential BP1.

Element N1 symbolizes, by way of example, a first circuit node of the bistable multivibrator KS, at which a memory content of the memory unit 110 is present in the form of an electrical potential, for example characterizing one of two possible states, e.g., “1” or “0.” A state that is inverse thereto is present in the form of an electrical potential at the second circuit node N2.

For writing and/or reading the memory unit, for example according to a conventional method, the access transistors 15, T6 are, for example, both activated via the word line SL1-1, i.e., for example, a gate-source voltage is applied to them, which is, for example, comparatively far above the threshold voltage of the access transistors T5, T6.

In the case of reading, according to exemplary embodiments, the potential at the circuit nodes N1, N2 can then be determined via the at least one bit line SL2a (or, for example, via both bit lines SL2a, SL2b), for example be detected by a voltage measurement.

In the case of writing, according to exemplary embodiments, a corresponding value can be specified via the at least one bit line SL2a (or, for example, via both bit lines SL2a, SL2b), for example in the form of a relevant electrical potential which is applied to the bit line(s).

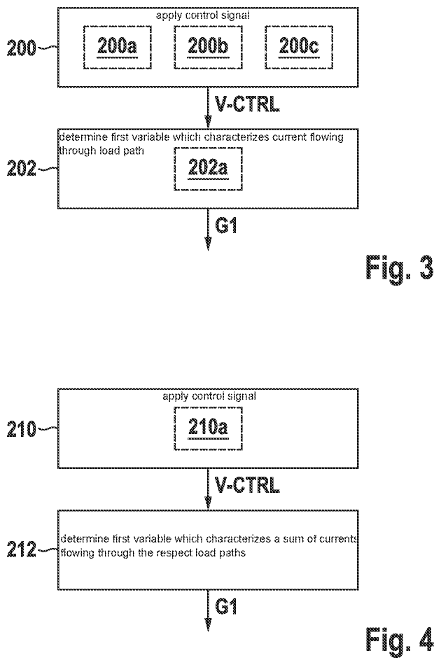

In contrast to the reading of the memory unit 110, in which the access transistors T5, T6, for example, are both activated via the word line SL1-1, i.e., for example, a gate-source voltage is applied to them, which, for example, is comparatively far above the threshold voltage of the access transistors T5, T6, in the application 200 according to further exemplary embodiments, a gate-source voltage is selected, for example applied, for at least the access transistor T5, for example for both access transistors T5, T6, for example again via the word line SL1-1 (see also block 200a according to FIG. 3), said voltage being, for example, less than or equal to the threshold voltage of the access transistors T5, T6, so that, for example, instead of a determination of the electrical potential of the circuit nodes N1, N2, the current I1a described above can be determined.

In further exemplary embodiments, the two access transistors 15, T6 are designed as field-effect transistors, for example of the MOSFET type, for example in the same or similar manner as the transistors T1, T2, T3, T4.

In further exemplary embodiments, FIG. 3, it is provided that the method comprises: the application 200b of the control signal V-CTRL to both access transistors T5, T6, for example via the primary control line, for example word line SL1-1. Thus, in further exemplary embodiments, for example, the determination 202 (FIG. 3) of the first variable G1 can be performed, for example, on the basis of two currents I1a, I1b, of which a first current I1a is a current flowing through the load path (e.g., drain-source path) T5-LS of the first access transistor T5, and of which a second current I1b is a current flowing through the load path of the second access transistor T6. In further exemplary embodiments, the first variable G1 can be determined on the basis of the first current I1a and of the second current I1b, for example using a differential measuring principle.

In further exemplary embodiments, FIG. 3, it is provided that the application 200 of the control signal V-CTRL to the control terminal of the at least one of the two access transistors T5, T6 in such a way that the load path of the at least one access transistor T5, T6 is at least partially electrically conductive, for example with respect to the high-resistance state of the load path of the at least one access transistor (but, for example, is less electrically conductive than in a low-resistance state, for example in the case of a field-effect transistor characterizable by a resistance R_{DS,on}), comprises: the application 200c of a control voltage to the control terminal of the at least one of the two access transistors, which control voltage is less than or equal to a threshold voltage of the at least one access transistor T5, T6.

In further exemplary embodiments, the setting of the control voltage V-CTRL to less than or equal to the threshold voltage of the at least one access transistor T5, T6, enables a, for example purposeful, “removal” of electrical charge from the bistable multivibrator KS, i.e., for example, a purposeful discharge of an electrical current from the bistable multivibrator KS through the at least one access transistor T5, T6, wherein a value of the current depends, for example, also on the state of the bistable multivibrator KS, i.e., the memory content of the memory unit 110.

In further exemplary embodiments, FIG. 2, it is provided that the memory device comprises a plurality of memory units, for example memory cells, 110-1, 110-2, . . . , 110-11, . . . , wherein the method comprises: the application 210 (FIG. 4) of the control signal V-CTRL, for example the control voltage, to a relevant control terminal of at least one of the two access transistors T5, T6 (FIG. 1) of the plurality of memory units 110-1, 110-2, . . . , 110-11, . . . in such a way that a load path of the relevant at least one access transistor of the plurality of memory units 110-1, 110-2, . . . , 110-11, . . . , is at least partially electrically conductive, for example with respect to a high-resistance state of the load path of the at least one access transistor (e.g., by selecting the control voltage to be less than or equal to the threshold voltage of the at least one access transistor); the determination 212 (FIG. 4) of the first variable G1 which characterizes a sum of currents flowing through the respective load paths of the at least one access transistor of the plurality of memory units 110-1, 110-2, . . . , 110-11, . . . , wherein this sum can, for example, be a summation current consisting of the currents of the individual access transistors, such as can be conducted, for example, via at least one of the secondary control lines, for example bit lines, for example to a device for determining the first variable or the summation current, for example comprising at least one measuring device.

FIG. 2 shows, by way of example, an arrangement of a plurality of memory units 110-1, 110-2, . . . , 110-11, . . . according to exemplary embodiments, said arrangement being in the form of a matrix (having columns and/or rows), wherein, for example, in each case, a primary control line, for example word line, SL1-1, SL1-2 is in each case assigned to a plurality of memory units 110-1, 110-2, 110-3, . . . , 110-9, 110-10, 110-11, . . . . For example, in further exemplary embodiments, the memory units 110-1, 110-2, 110-3, . . . of a first row according to FIG. 2 can thus be controlled by means of the first word line SL1-1, for example at least temporarily with the control voltage V-CTRL (FIG. 1), for example, for the application 200a to the access transistors T5, T6. In a comparable manner, in further exemplary embodiments, the memory units 110-9, 110-10, 110-11, . . . of a second row according to FIG. 2 can, for example, thus be controlled by means of the second word line SL1-2, for example at least temporarily with the control voltage V-CTRL (FIG. 1), for example for the application to the access transistors T5, T6, etc.

For example, each of the plurality of memory units 110-1, 110-2, 110-3, . . . , 110-9, 110-10, 110-11, . . . according to FIG. 2 has a configuration similar to or identical to FIG. 1, wherein, for example, corresponding bit lines are not shown in FIG. 2 for reasons of clarity. By way of example, however, the ellipses “ . . . ” of FIG. 1 symbolize an optional combination of the memory unit 110 according to FIG. 1 with further memory units not shown in FIG. 1, for example similar to the arrangement of FIG. 2, wherein the memory unit 110 according to FIG. 1 shares the word line SL1-1 and/or the bit lines SL2a, SL2b with in each case further other memory units.

Element I2a in FIG. 1 also symbolizes, by way of example, a current which is removed during an application 200 (FIG. 3) to a further memory unit (not shown in FIG. 1) according to exemplary embodiments, and which can be added to the current I1a of the multivibrator KS, for example to form the first variable G1, for example implicitly, for example by an assignment to the same bit line SL2a.

In further exemplary embodiments, FIG. 4, it is provided that the application 210 is performed using at least the first primary control line SL1-1; see block 210a in FIG. 4.

In other words, in further exemplary embodiments, it is provided that a plurality of memory units, for example memory cells, of the memory device are activated, for example simultaneously, for example by the application of the control signal V-CTRL, for example the control voltage, to a relevant control terminal of at least one of the two access transistors T5, T6 (FIG. 1) of the plurality of memory units in such a way that a load path of the relevant at least one access transistor of the plurality of memory units is at least partially electrically conductive, for example with respect to a high-resistance state of the load path of the at least one access transistor (e.g., by selecting the control voltage to be less than or equal to the threshold voltage of the at least one access transistor).

In further exemplary embodiments, the activation can be effected, for example, by applying the relevant control voltage V-CTRL, for example less than or equal to the threshold voltage, via at least the first primary control line, for example a word line, SL1-1, optionally also via a plurality (e.g., if present) of primary control lines, for example word lines; see FIG. 2. In further exemplary embodiments, a current that can be discharged here from the relevant plurality of memory units can be discharged, for example, via at least one bit line associated with the relevant memory unit (and optionally added to currents of other, for example identically activated, memory units), and optionally, for example, measured.

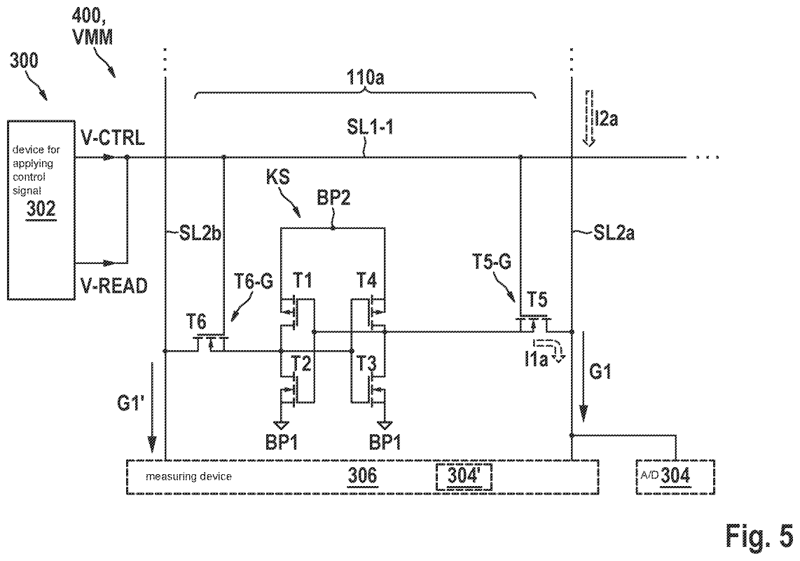

In further exemplary embodiments, FIG. 3, it is provided that the method comprises: the determination 202a of the first variable G1 with a, for example current-based, analog/digital converter device 304 (see FIG. 5), for example a differential analog/digital converter device, and/or with another determination device suitable for this purpose, for example a measuring device.

In further exemplary embodiments, it is provided that the determination device, for example measuring device, is connected and/or connectable to at least one of the bit lines SL2a, SL2b (FIG. 1). In further exemplary embodiments, it is provided that the determination device, for example measuring device, can, for example, be combined with, for example integrated in, an existing, for example conventional, measuring device, which is designed, for example, in the case of a complete activation of the access transistors T5, T6, for reading a content of the memory unit(s), which can be performed, for example, by means of a voltage measurement.

FIG. 5 schematically shows a simplified circuit diagram according to further exemplary embodiments. Shown is a memory unit 110a which, for example, comprises a configuration similar or identical to the configuration 110 according to FIG. 1.

Further exemplary embodiments, FIG. 5, relate to a device 300 for performing the method according to the embodiments.

In further exemplary embodiments, FIG. 5, it is provided that the device 300 comprises at least one of the following elements: a) device 302 for the application of the control signal V-CTRL to the control terminal T5-G, T6-G of at least one of the two access transistors T5, T6, for example via the first primary control line SL1-1; b) analog/digital converter device 304, for example current-based analog/digital converter device, for example differential analog/digital converter device; c) measuring device 306, for example measuring amplifier, for the determination of at least one electrical potential or one potential difference which is or are associated with at least one of the secondary control lines, for example bit lines, SL2a, SL2b.

For example, the first variable G1, for example as a summation current I1a+I2a, can be detected by means of the analog/digital converter device 304.

In further exemplary embodiments, the analog/digital converter device 304 can be assigned, for example, to a conventional memory cell or to a conventional measuring device 306.

In further exemplary embodiments, the analog/digital converter device can also be integrated, for example, in a conventional measuring device 306, such as can, for example, be used for a conventional reading of the memory unit 110a; see the block 304′ according to FIG. 5.

In further exemplary embodiments, FIG. 5, the device 302 is designed to output, at least temporarily, the control voltage V-CTRL to the first word line SL1-1, for example for the application 200.

In further exemplary embodiments, FIG. 5, the device 302 is designed to output, at least temporarily, a readout voltage V-READ, for example for a conventional reading of the memory unit 110a, to the first word line SL1-1 (and/or a voltage for writing information, not shown).

In other words, in further exemplary embodiments, the device 300 can be used, for example by means of the device 302, at least temporarily, for example for a conventional reading and/or writing of information regarding the memory device 110a, and the device 300 can temporarily be used, for example by means of the device 302, for example for an execution of aspects according to exemplary embodiments, for example for an application 200 (FIG. 3) and/or a determination 202 (e.g., by means of the block 304, 304′).

Element G1 of FIG. 5 symbolizes the determination of the first variable G1 associated with the individual bit line SL2a according to exemplary embodiments.

Element G1′ of FIG. 5, together with element G1, symbolizes the determination of the first variable associated with the two bit lines SL2a, SL2b according to further exemplary embodiments, for example on the basis of a differential evaluation principle.

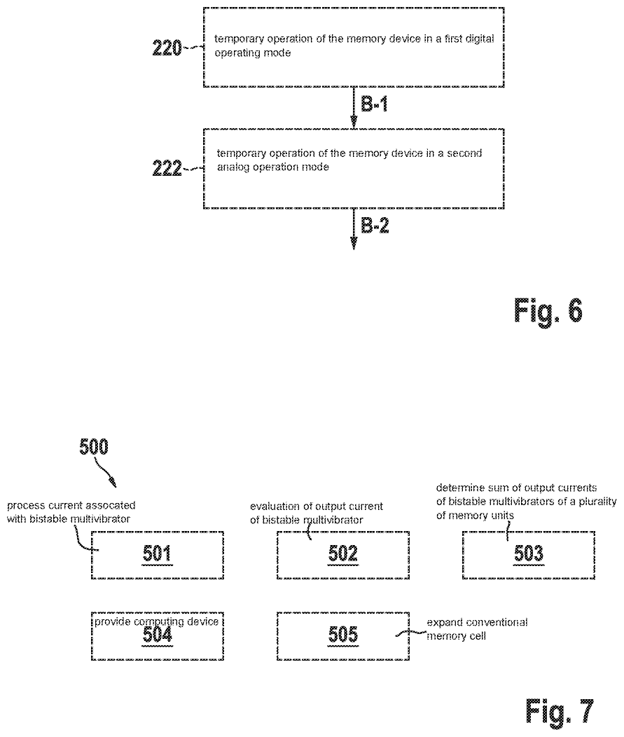

In further exemplary embodiments, FIG. 6, it is provided that the method comprises at least one of the following elements: a) at least a temporary operation 220 of the memory device 100 in a first, for example digital, operating mode, B-1, in which a control voltage greater than the threshold voltage of the at least one of the two access transistors is used for application to or controlling the control terminal of the at least one of the two access transistors (e.g., for conventional reading of the memory content); b) at least a temporary operation 222 of the memory device 100 in a second, for example analog, operating mode, B-2, in which a control voltage less than or equal to the threshold voltage of the at least one of the two access transistors is used for the application 200 to the control terminal of the at least one of the two access transistors (for example, for determining at least one current or the first variable G1, for example according to exemplary embodiments). In further exemplary embodiments, the two operating modes B-1, B-2 can be changed dynamically, i.e., during operation of the memory device 100, for example according to a time multiplex principle.

In further exemplary embodiments, it is also possible to operate in the first operating mode B-1 some memory units of a memory device, see FIG. 2, comprising a plurality of memory units and, for example, also a plurality of word lines, and to operate, for example simultaneously therewith, other memory units of the same memory device in the second operating mode B-2. A granularity for this purpose can be specified in further exemplary embodiments, for example by an architecture of the memory units per word line or the like.

In further exemplary embodiments, FIG. 5, it is provided that the device 300 has at least one memory device which comprises at least one memory unit 110a, for example a memory cell.

In further exemplary embodiments, it is provided that a conventional memory unit or memory device can be expanded by at least one aspect of the principle according to the embodiments, for example by assignment, for example provision, of at least one of the following elements: a) device 302 for the application of the control signal to the control terminal of at least one of the two access transistors, for example via the first primary control line; b) analog/digital converter device 304, for example current-based analog/digital converter device, for example differential analog/digital converter device; c) measuring device 306, for example measuring amplifier, for determining at least one electrical potential or one potential difference which is or are associated with at least one of the secondary control lines, for example bit lines. In further exemplary embodiments, it is provided that at least one of the aforementioned aspects a), b), c) can be integrated into the conventional memory unit or memory device or can be assigned to the conventional memory unit or memory device.

Further exemplary embodiments, FIG. 5, relate to a computing device 400, for example vector matrix multiplication device VMM, comprising at least one device 300 according to the embodiments.

Further exemplary embodiments, FIG. 7, relate to a use 500 of the method according to the embodiments and/or of the device 300 according to the embodiments and/or of the computing device 400, VMM, according to the embodiments for at least one of the following aspects: a) the processing of 501 of a current associated with the bistable multivibrator KS; b) the evaluation 502 of an output current of the bistable multivibrator KS; c) the determination 503 of a sum of output currents of bistable multivibrators of a plurality of memory units 110-1, 110-2, . . . , for example memory cells, of the device 300; d) the provision 504 of a computing device 400, for example for compute-in-memory methods, for example for algorithms of artificial intelligence, for example for executing an inference of an artificial neural network; e) the expansion 505 of a, for example conventional, memory cell, for example for reading or determining an output current of the bistable multivibrator KS.

In further exemplary embodiments, the principle according to the embodiments can be used, for example, to modify, for example expand, a, for example existing, SRAM (static RAM) macro (e.g., structure comprising a plurality of memory cells), for example without changing the memory cells as such, whereby, for example, the size of the existing memory cells does not change, for example just as little as their acceptance on the market.

In further exemplary embodiments, the principle according to the embodiments can be used, for example solely, to modify the device 302, and/or to supplement the device 304, 304′, for example to integrate it into an existing device 306 for a conventional reading of the memory cells. Alternatively or additionally, for example, a conventional device 306 for a conventional reading of the memory cells can be expanded in such a way that it can determine the first variable G1, for example by detecting, for example measuring, currents associated with at least one bit line SL2a, SL2b.

In further exemplary embodiments, the application 200 (FIG. 3), for example by means of the device 302, can, for example, be performed simultaneously for a plurality of word lines SL1-1, SL 1-2, . . . , for example by means of a control voltage V-CTRL less than or equal to the threshold voltage of the access transistors T5, T6 used. As already described above, the application 200 with the control voltage V-CTRL less than or equal to the threshold voltage of the access transistors T5, T6 used in further exemplary embodiments does not already effect an activation of the access transistors T5, T6 used, for example for reading or writing, but rather the production of a non-vanishing (but not already maximal) conductivity of their relevant load path in order to remove the current mentioned. In further exemplary embodiments, a relevant current of a plurality of memory cells can thus, for example, be added along, for example, at least one of the bit lines SL2a, SL2b, for example for the determination 202 of the first variable G1. In further exemplary embodiments, a differential operation G1, G1′ (FIG. 5) is provided for the determination 202, which, for example, can impede side channel attacks on implementations of the device 300 according to the embodiments.

### Sponsorship and Support Information

The project that has led to this application was sponsored by the joint venture ECSEL (JU) within the framework of sponsorship agreement no. 826655. The JU is supported by the research and innovation program Horizon 2020 of the European Union and Belgium, France, Germany, the Netherlands, Switzerland.

What is claimed is:

1. A method for operating a memory device which includes at least one memory unit, wherein the at least one memory unit includes a bistable multivibrator, and two access transistors for controllable connection of the bistable multivibrator to two secondary control lines associated with the at least one memory unit, wherein the connection of the bistable multivibrator to the two secondary control lines is controllable using a first primary control line, the method comprising the following steps:
applying a control signal to a control terminal of at least one of the two access transistors in such a way that a load path of the at least one access transistor is at least partially electrically conductive with respect to a high-resistance state of the load path of the at least one access transistor less electrically conductive with respect to a low-resistance state of the load path of the at least one access transistor; and
determining a first variable which characterizes at least one current flowing through the load path of the at least one access transistor.

2. The method according to claim 1, wherein the memory unit is a memory cell.

3. The method according to claim 1, wherein the second control lines are bit lines.

4. The method according to claim 1, wherein the first primary control line is a word line.

5. The method according to claim 1, wherein the application of the control signal to the control terminal of the at least one of the two access transistors is performed via the first primary control line.

6. The method according to claim 1, wherein the application of the control signal including applying the control signal to both access transistors via the primary control line.

7. The method according to claim 1, wherein the application of the control signal to the control terminal of the at least one of the two access transistors in such a way that the load path of the at least one access transistor is at least partially electrically conductive with respect to the high-resistance state of the load path of the at least one access transistor includes: applying a control voltage to the control terminal of the at least one of the two access transistors, which control voltage is less than or equal to a threshold voltage of the at least one access transistor.

8. The method according to claim 1, wherein the memory device includes a plurality of memory units, wherein the method includes: applying the control signal to a relevant control terminal of at least one of the two access transistors of the plurality of memory units in such a way that a load path of the relevant at least one access transistor of the plurality of memory units is at least partially electrically conductive with respect to a high-resistance state of the load path of the at least one access transistor, the determination of the first variable characterizing a sum of currents flowing through the respective load paths of the at least one access transistor of the plurality of memory units.

9. The method according to claim 8, wherein the application is performed using at least the first primary control line.

10. The method according to claim 1, wherein the first variable is detected with a current-based, analog/digital converter device.

11. The method according to claim 10, wherein the analog/digital converter device is a differential analog/digital converter device.

12. The method according to claim 1, further comprising at least one of the following elements: a) at least a temporary operation of the memory device in a first digital operating mode in which a control voltage greater than a threshold voltage of the at least one of the two access transistors is used for the application to the control terminal of the at least one of the two access transistors; b) at least a temporary operation of the memory device in a second analog operating mode, in which a control voltage less than or equal to the threshold voltage of the at least one of the two access transistors is used for the application to the control terminal of the at least one of the two access transistors.

13. A device configured to operate a memory device which includes at least one memory unit, wherein the at least one memory unit includes a bistable multivibrator, and two access transistors for controllable connection of the bistable multivibrator to two secondary control lines associated with the at least one memory unit, wherein the connection of the bistable multivibrator to the two secondary control lines is controllable using a first primary control line, the device configured to:
apply a control signal to a control terminal of at least one of the two access transistors in such a way that a load path of the at least one access transistor is at least partially electrically conductive with respect to a high-resistance state of the load path of the at least one access transistor less electrically conductive with respect to a low-resistance state of the load path of the at least one access transistor; and
determine a first variable which characterizes at least one current flowing through the load path of the at least one access transistor.

14. The device according to claim 13, wherein the device comprises at least one of the following elements: a) a device for the application of the control signal to the control terminal of at least one of the two access transistors via the first primary control line; b) a current-based analog/digital converter device; c) a measuring device including a measuring amplifier, for determining at least one electrical potential or one potential difference associated with at least one of the secondary control lines.

15. The device according to claim 13, further comprising the at least one memory device.

16. A computing device including a vector matrix multiplication device, comprising:
a device configured to operate a memory device which includes at least one memory unit, wherein the at least one memory unit includes a bistable multivibrator, and two access transistors for controllable connection of the bistable multivibrator to two secondary control lines associated with the at least one memory unit, wherein the connection of the bistable multivibrator to the two secondary control lines is controllable using a first primary control line, the device configured to:
apply a control signal to a control terminal of at least one of the two access transistors in such a way that a load path of the at least one access transistor is at least partially electrically conductive with respect to a high-resistance state of the load path of the at least one access transistor less electrically conductive with respect to a low-resistance state of the load path of the at least one access transistor; and
determine a first variable which characterizes at least one current flowing through the load path of the at least one access transistor.

17. The method according to claim 1, wherein the method is used for: a) processing of a current associated with the bistable multivibrator; b) evaluation of an output current of the bistable multivibrator; c) determination of a sum of output currents of bistable multivibrators of a plurality of memory units; d) provision of a computing device for executing an inference of an artificial neural network; e) expansion of a conventional memory cell for reading or determining an output current of the bistable multivibrator.
